(19) United States
(12) Patent Application Publication
(10) Pub. No.: US 2026/0247694 A1
(43) Pub. Date: Aug. 20, 2026

(54) SEMICONDUCTOR DEVICE AND METHOD OF MANUFACTURING THE SAME

(71) Applicant: Renesas Electronics Corporation, Tokyo (JP)

(72) Inventor: Yuki MURAYAMA, Tokyo (JP)

(21) Appl. No.: 19/423,040

(22) Filed: Dec. 17, 2025

(30) Foreign Application Priority Data
Feb. 19, 2025 (JP) 2025-025212

(51) Int. Cl. H10D 84/80; H10D 84/01

(52) U.S. Cl. CPC H10D 84/813; H10D 84/01

(57) ABSTRACT

A semiconductor device includes a MOS capacitive element and a MOS transistor element. The MOS capacitive element includes a first impurity region formed at a main surface of a semiconductor substrate, a first insulating film formed on the main surface of the semiconductor substrate so as to cover the first impurity region, and a first electrode facing the first impurity region with the first insulating film interposed therebetween. The MOS transistor element includes a second impurity region formed at the main surface of the semiconductor substrate, a second insulating film formed on the main surface of the semiconductor substrate so as to cover the second impurity region, and a second electrode facing the second impurity region with the second insulating film interposed therebetween. An impurity concentration in the first electrode is higher than an impurity concentration in the second electrode.

### CROSS-REFERENCE TO RELATED APPLICATIONS

The disclosure of Japanese Patent Application No. 2025-025212 filed on February 19, 2025 including the specification, drawings and abstract is incorporated herein by reference in its entirety.

### BACKGROUND

The present disclosure relates to a semiconductor device and a method of manufacturing the semiconductor device.

There is disclosed a technique listed below.

[Patent Document 1] Japanese Unexamined Patent Application Publication No. 2007-242660

Patent Document 1 discloses a metal oxide semiconductor (MOS) capacitive element. The MOS capacitive element of Patent Document 1 includes a polysilicon electrode as one electrode, an impurity region as the other electrode, and an insulating film between the polysilicon layer and the impurity region. The MOS capacitive element of Patent Document 1 includes a high-concentration region containing a high-concentration impurity as the other electrode, thereby shifting a threshold voltage to a low voltage side.

### SUMMARY

In the MOS capacitive element of Patent Document 1, when an insulating film is formed on the high-concentration region as the other electrode, there is a possibility that the insulating film becomes thicker due to accelerated oxidation. Consequently, the capacitance of the MOS capacitive element may decrease.

The other objects and novel features will become apparent from the descriptions of this specification and the accompanying drawings.

According to one embodiment, a semiconductor device includes a MOS capacitive element and a MOS transistor element, in which the MOS capacitive element includes a first impurity region formed in a semiconductor substrate and disposed at a main surface of the semiconductor substrate, a first insulating film formed on the main surface of the semiconductor substrate so as to cover the first impurity region, and a first electrode formed on the first impurity region via the first insulating film, the MOS transistor element includes a second impurity region formed in the semiconductor substrate and disposed at the main surface of the semiconductor substrate, a second insulating film formed on the main surface of the semiconductor substrate so as to cover the second impurity region, and a second electrode formed on the second impurity region via the second insulating film, and an impurity concentration in the first electrode is higher than an impurity concentration in the second electrode.

According to one embodiment, a method of manufacturing a semiconductor device including a MOS capacitive element and a MOS transistor element includes a step of forming a first insulating film and a second insulating film on a main surface of a semiconductor substrate, a step of forming an electrode material having a first portion and a second portion on the main surface of the semiconductor substrate so as to cover the first insulating film and the second insulating film, the first portion of the electrode material being located on the first insulating film, and the second portion of the electrode material being located on the second insulating film, a step of forming a first impurity region in the semiconductor substrate by implanting an impurity into the first portion of the electrode material and a portion of the semiconductor substrate located under the first portion of the electrode material in a state where the second portion of the electrode material is covered with a mask, and a step of forming a first electrode from the first portion and forming a second electrode from the second portion by processing the electrode material, the MOS capacitive element includes the first impurity region, the first insulating film, and the first electrode, the MOS transistor element includes a second impurity region formed in the semiconductor substrate, the second insulating film, and the second electrode, and an impurity concentration in the first electrode is higher than an impurity concentration in the second electrode.

According to the embodiment above, it is possible to provide a semiconductor device capable of improving the capacitance characteristics of a MOS capacitive element and a method of manufacturing the semiconductor device.

### BRIEF DESCRIPTION OF THE DRAWINGS

FIG. 1 is a cross-sectional view illustrating a MOS capacitive element in a semiconductor device according to first comparative example.

FIG. 2 is a graph illustrating characteristics of the MOS capacitive element in the semiconductor device according to first comparative example, where the horizontal axis represents a voltage and the vertical axis represents a capacitance.

FIG. 3 is a cross-sectional view illustrating a MOS capacitive element in a semiconductor device according to second comparative example.

FIG. 4 is a graph illustrating characteristics of the MOS capacitive element in the semiconductor device according to second comparative example, where the horizontal axis represents a voltage and the vertical axis represents a capacitance.

FIG. 5 is a cross-sectional view illustrating a MOS capacitive element in a semiconductor device according to third comparative example.

FIG. 6 is a cross-sectional view illustrating the MOS capacitive element according to first comparative example and the MOS capacitive element according to second comparative example.

FIG. 7 is a schematic view illustrating the MOS capacitive element of third comparative example.

FIG. 8 is a cross-sectional view illustrating a semiconductor device according to a first embodiment.

FIG. 9 is a plan view illustrating details of a MOS capacitive element in the semiconductor device according to the first embodiment, and illustrates a main surface of a semiconductor substrate.

FIG. 10 is a cross-sectional view illustrating details of the MOS capacitive element in the semiconductor device according to the first embodiment, and illustrates a cross section taken along line A-A in FIG. 9.

FIG. 11 is a cross-sectional view illustrating a method of manufacturing the semiconductor device 1 according to the first embodiment.

FIG. 12 is a cross-sectional view illustrating the method of manufacturing the semiconductor device 1 according to the first embodiment.

FIG. 13 is a cross-sectional view illustrating the method of manufacturing the semiconductor device 1 according to the first embodiment.

FIG. 14 is a cross-sectional view illustrating the method of manufacturing the semiconductor device 1 according to the first embodiment.

FIG. 15 is a cross-sectional view illustrating the method of manufacturing the semiconductor device 1 according to the first embodiment.

FIG. 16 is a simulation result illustrating a capacitance of a MOS capacitive element of fourth comparative example.

FIG. 17 is a simulation result illustrating a capacitance of the MOS capacitive element of the first embodiment.

FIG. 18 is a graph illustrating the capacitances of the MOS capacitive elements of the first embodiment and fourth comparative example, where the horizontal axis represents a voltage and the vertical axis represents a capacitance.

### DETAILED DESCRIPTION

For clarity of description, the following description and drawings are omitted and simplified as appropriate. In the drawings, hatching or the like may be omitted even in a cross section when it would otherwise make the drawings complicated or when the distinction from a space is clear. In each drawing, the same elements are denoted by the same reference numerals, and redundant description is omitted as necessary. Some reference numerals may be omitted so as to avoid making the drawings complicated.

In the present specification, the fact that the conductivity type of a semiconductor is N type means that only electrons are charge carriers, or means that both electrons and holes are charge carriers, but the density of the electrons is higher than the density of the holes and the electrons are major charge carriers. In the present specification, the fact that the conductivity type of a semiconductor is P type means that only holes are charge carriers, or means that both electrons and holes may be charge carriers, but the density of the holes is higher than the density of the electrons and the holes are major charge carriers.

Note that N+ type and P+ type represent an N conductivity type and a P conductivity type which have lower resistance than the N type and the P type, respectively. P- type and N- type represent an N conductivity type and a P conductivity type which have higher resistance than the N type and the P type, respectively. Therefore, the N type and the P type represent the N conductivity type and the P conductivity type which have resistance between those of the N+ type and the P+ type and those of the P- type and the N- type, respectively. Hereinafter, the same meaning is given unless otherwise specified.

The N conductivity type may be referred to as a first conductivity type, and the P conductivity type may be referred to as a second conductivity type. Meanwhile, the N conductivity type may be referred to as a second conductivity type, and the P conductivity type may be referred to as a first conductivity type. Also, a semiconductor device in which the conductivity types of the respective configurations of the present disclosure are reversed is also included in the scope of the technical idea of the present disclosure. Further, resistances of the respective N+ type, N type, and N- type semiconductor layers are examples. Although not stated otherwise, semiconductor layers may have higher resistances than those illustrated in the present disclosure or lower resistances than those illustrated in the present disclosure. Magnitude relationships of the resistances of the respective N+ type, N type, and N- type semiconductor layers may be reversed in some cases. Similarly, resistances of the respective P+ type, P type, and P- type semiconductor layers are examples. Although not stated otherwise, semiconductor layers may have higher resistances than those illustrated in the present disclosure or lower resistances than those illustrated in the present disclosure. Magnitude relationships of the resistances of the respective P+ type, P type, and P- type semiconductor layers may be reversed in some cases.

First, in FIRST COMPARATIVE EXAMPLE to THIRD COMPARATIVE EXAMPLE, semiconductor devices according to comparative examples will be described. Thereafter, in PROBLEMS NEWLY FOUND BY INVENTOR, the problems newly found by the inventor with respect to the semiconductor devices of the comparative examples will be described. Then, in FIRST EMBODIMENT, a semiconductor device according to a first embodiment and a method of manufacturing the semiconductor device will be described in comparison with each comparative example. In this way, the semiconductor device and the method of manufacturing the semiconductor device according to the present embodiment will be made clearer. Note that each comparative example and the problems newly found by the inventor are also within the scope of the technical idea of the embodiment.

### FIRST COMPARATIVE EXAMPLE

FIG. 1 is a cross-sectional view illustrating a MOS capacitive element 110 in a semiconductor device according to first comparative example. As illustrated in FIG. 1, the MOS capacitive element 110 of first comparative example includes an N type impurity region 111, an insulating film 112, an electrode 113, an N type well region 114, an N+ type impurity region 115, a wiring 116, and a wiring 117. The N type impurity region 111, the N type well region 114, and the N+ type impurity region 115 are formed in a semiconductor substrate 100. The N type impurity region 111 may be referred to as a channel region.

Here, for example, a direction orthogonal to a main surface 101 of the semiconductor substrate 100 is a Z-axis direction. Two directions parallel to the main surface 101 of the semiconductor substrate 100 and orthogonal to each other are an X-axis direction and a Y-axis direction. The +Z-axis direction is referred to as “upward,” and the -Z-axis direction is referred to as “downward.” Note that the upper side and the lower side are made for convenience of description of the MOS capacitive element 110 and the like, and do not indicate a direction in which the MOS capacitive element 110 and the like are actually arranged.

The N type impurity region 111 is formed at the main surface 101 of the semiconductor substrate 100. The N+ type impurity region 115 is formed at the main surface 101 of the semiconductor substrate 100. A plurality of N+ type impurity regions 115 may be formed. The plurality of N+ type impurity regions 115 is formed so as to sandwich the N type impurity region 111. The N type well region 114 is formed under the N type impurity region 111 and the N+ type impurity region 115. The N type well region 114 may be integrated with the N type impurity region 111. That is, the N type impurity region 111 may be a part of the N type well region 114. The insulating film 112 is formed on the main surface 101 of the semiconductor substrate 100. For example, the insulating film 112 is formed on the N type impurity region 111 and on the plurality of N+ type impurity regions 115.

The electrode 113 is formed over the N type impurity region 111 via the insulating film 112. Therefore, the insulating film 112 is formed between the N type impurity region 111 and the electrode 113. The wiring 116 is connected to the electrode 113. The electrode 113 includes, for example, polysilicon containing an N type impurity. The wiring 117 passes through the insulating film 112 and is connected to the N+ type impurity region 115. The MOS capacitive element 110 can be operated by applying a voltage between the wiring 116 and the wiring 117.

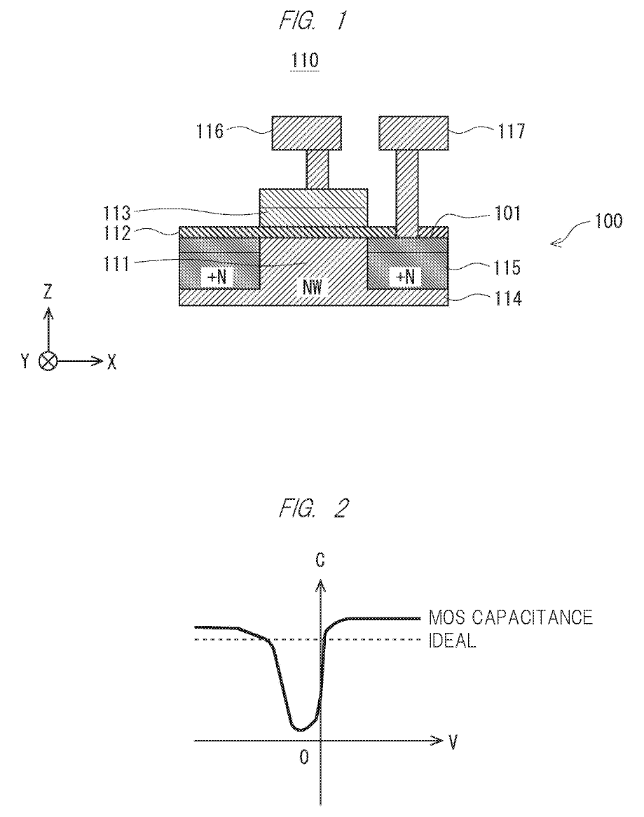

FIG. 2 is a graph illustrating characteristics of the MOS capacitive element 110 in the semiconductor device according to first comparative example, where the horizontal axis represents a voltage V and the vertical axis represents a capacitance C. As illustrated in FIG. 2, in the MOS capacitive element 110 of first comparative example, a capacitance change occurs due to the formation of an inversion layer when a negative voltage and a positive voltage (±voltage) are applied. Therefore, the MOS capacitive element 110 of first comparative example is greatly different from ideal characteristics.

### SECOND COMPARATIVE EXAMPLE

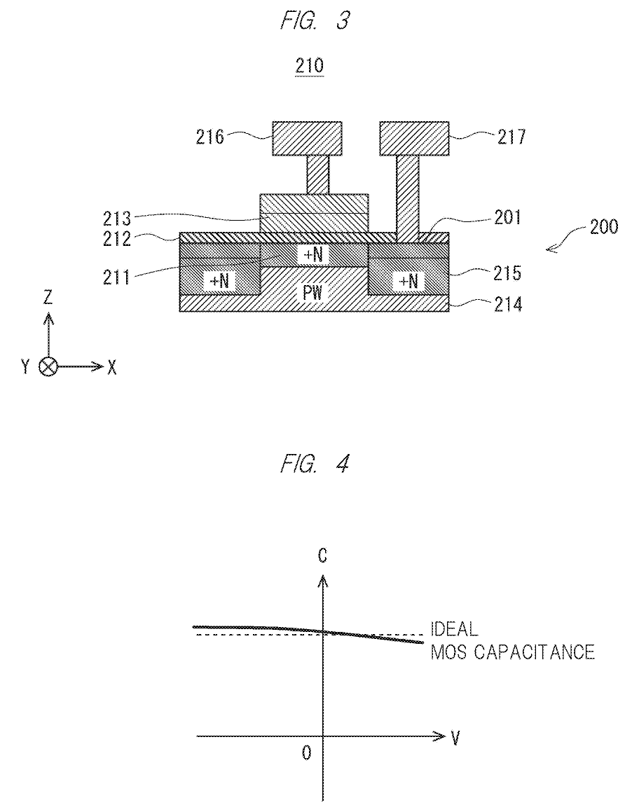

FIG. 3 is a cross-sectional view illustrating a MOS capacitive element 210 in a semiconductor device according to second comparative example. As illustrated in FIG. 3, the MOS capacitive element 210 of second comparative example includes an N+ type impurity region 211, an insulating film 212, an electrode 213, a P type well region 214, an N+ type impurity region 215, a wiring 216, and a wiring 217. The N+ type impurity region 211, the P type well region 214, and the N+ type impurity region 215 are formed in a semiconductor substrate 200. The N+ type impurity region 211 may be referred to as a channel region.

The N+ type impurity region 211 is formed at a main surface 201 of the semiconductor substrate 200. The N+ type impurity region 215 is formed at the main surface 201 of the semiconductor substrate 200. A plurality of N+ type impurity regions 215 may be formed. The plurality of N+ type impurity regions 215 is formed so as to sandwich the N+ type impurity region 211. The P type well region 214 is formed under the N+ type impurity region 211 and the N+ type impurity region 215. The insulating film 212 is formed on the main surface 201 of the semiconductor substrate 200.

The electrode 213 is formed over the impurity region 211 via the insulating film 212. Therefore, the insulating film 212 is formed between the N+ type impurity region 211 and the electrode 213. The electrode 213 includes, for example, polysilicon containing an N type impurity. The wiring 216 is connected to the electrode 213. The wiring 217 passes through the insulating film 212 and is connected to the N+ type impurity region 215. The MOS capacitive element 210 can be operated by applying a voltage between the wiring 216 and the wiring 217.

FIG. 4 is a graph illustrating characteristics of the MOS capacitive element 210 in the semiconductor device according to second comparative example, where the horizontal axis represents a voltage V and the vertical axis represents a capacitance C. As illustrated in FIG. 4, in the MOS capacitive element 210 of second comparative example, as compared with the MOS capacitive element 110 of first comparative example, the impurity concentration of the N+ type impurity region 211 as a channel region is high, and the impurity region 211 forms a high-concentration region. As a result, the MOS capacitive element 210 can shift a threshold voltage to a low voltage side. Therefore, the MOS capacitive element 210 operates in an accumulation region. For this reason, the MOS capacitive element 210 has a characteristic that the bias dependency can be reduced. The MOS capacitive element 210 of second comparative example can approach ideal characteristics.

### THIRD COMPARATIVE EXAMPLE

FIG. 5 is a cross-sectional view illustrating a MOS capacitive element 310 in a semiconductor device according to third comparative example. As illustrated in FIG. 5, the MOS capacitive element 310 of third comparative example includes a P type well region 311, an insulating film 312, an electrode 313, and an N+ type impurity region 315. The P type well region 311 and the N+ type impurity region 315 are formed in a semiconductor substrate 300. The insulating film 312 is formed on a main surface 301 of the semiconductor substrate 300. For example, the insulating film 312 is formed on the P type well region 311. The electrode 313 is formed over the P type well region 311 via the insulating film 312. Therefore, the insulating film 312 is formed between the P type well region 311 and the electrode 313. The electrode 313 includes, for example, polysilicon containing an N type impurity. The MOS capacitive element 310 can be operated by applying a voltage between the electrode 313 and the N+ type impurity region 315.

### PROBLEMS NEWLY FOUND BY INVENTOR

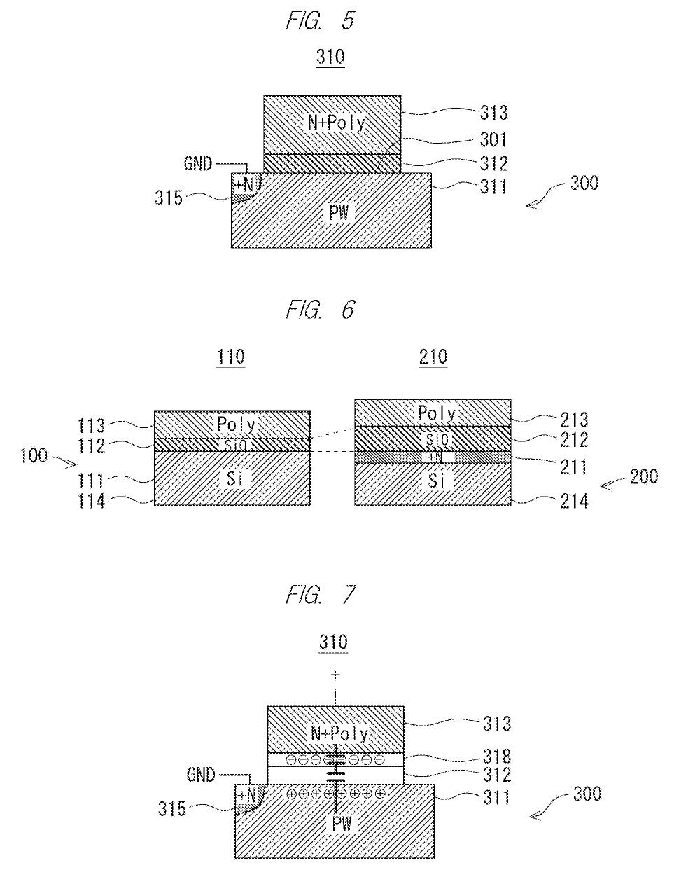

FIG. 6 is a cross-sectional view illustrating the MOS capacitive element 110 according to first comparative example and the MOS capacitive element 210 according to second comparative example. As illustrated in FIG. 6, in the process of manufacturing the MOS capacitive element 210 of second comparative example, the N+ type impurity region 211 is formed in the semiconductor substrate 200 by implanting an N type impurity having a high concentration into the semiconductor substrate 200, and then, for example, an oxide film is formed as the insulating film 212. At this time, the thickness of the insulating film 212 may increase due to the accelerated oxidation of the semiconductor substrate 200. In that case, the insulating film 212 of the MOS capacitive element 210 of second comparative example is thicker than the insulating film 112 of the MOS capacitive element 110 of first comparative example. As a result, the capacitance of the MOS capacitive element 210 of second comparative example decreases.

Specifically, for example, when silicon (Si) is contained as the semiconductor substrate 100 and the semiconductor substrate 200, the N+ type impurity region 211 is formed at the upper surface of the silicon, whereby the thickness of the insulating film 212 becomes, for example, 1.7 times due to the accelerated oxidation. As the thickness of the insulating film 212 is increased in this manner, the capacitance per unit area in the MOS capacitive element 210 of second comparative example decreases.

FIG. 7 is a schematic view illustrating the MOS capacitive element 310 of third comparative example. In FIG. 7, symbols of capacitors are displayed in an overlapping manner. As illustrated in FIG. 7, the electrode 313 is formed by, for example, implanting a high-concentration impurity as a dopant into polysilicon to which no impurity is added, and then performing activation annealing of the dopant. Implantation of the high-concentration impurity into the electrode 313 may be performed simultaneously with implantation of an impurity for forming a source and a drain of a MOS transistor. The lower portion of the electrode 313 has a lower dopant concentration as compared with the upper portion of the electrode 313. Therefore, there is a case where the activation rate of the lower portion of the electrode 313 decreases due to a slight variation in the processing temperature in the activation annealing after the implantation of the impurity. In that case, when a voltage is applied to the MOS capacitive element 310, a depletion layer 318 may be formed in the lower portion of the electrode 313. Therefore, the capacitance decreases due to depletion of the electrode 313.

### FIRST EMBODIMENT

Next, a semiconductor device 1 according to the present first embodiment will be described. One object of the semiconductor device 1 of the present first embodiment is to solve the problem of the formation of the inversion layer of first comparative example, the problem of the accelerated oxidation of the insulating film 212 of second comparative example, and the problem of the depletion of the lower portion of the electrode 313 of third comparative example without increasing the cost.

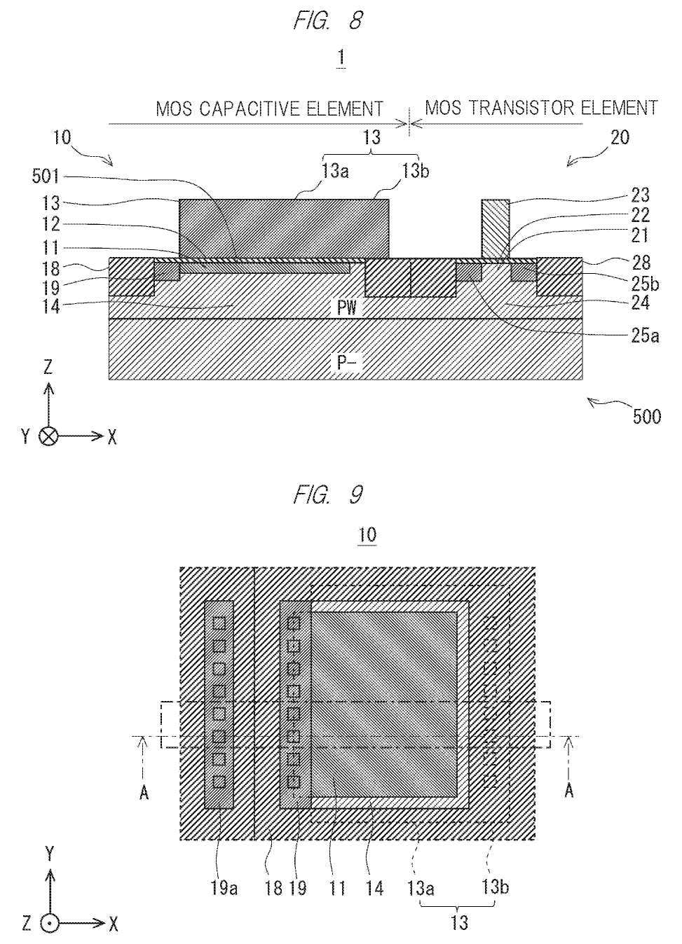

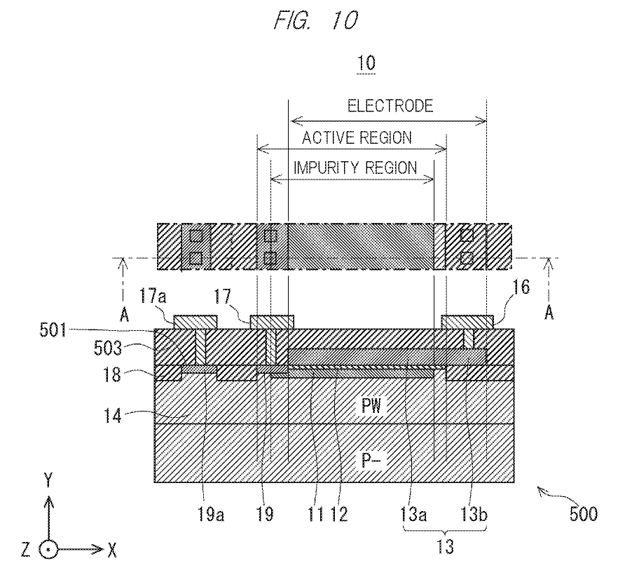

FIG. 8 is a cross-sectional view illustrating the semiconductor device 1 according to the first embodiment. FIG. 9 is a plan view illustrating details of a MOS capacitive element 10 in the semiconductor device 1 according to the first embodiment, and illustrates a main surface 501 of a semiconductor substrate 500. FIG. 10 is a cross-sectional view illustrating details of the MOS capacitive element 10 in the semiconductor device 1 according to the first embodiment, and illustrates a cross section taken along line A-A in FIG. 9. In FIG. 8, a P+ type contact region 19a for controlling the voltage of a P type well region 14 in the MOS capacitive element 10 is omitted. FIG. 10 illustrates a part of FIG. 9.

As illustrated in FIG. 8 to FIG. 10, the semiconductor device 1 of the present first embodiment includes the MOS capacitive element 10 and a MOS transistor element 20. Although only the MOS transistor element 20 of N type is illustrated in FIG. 8, the semiconductor device 1 may include the MOS transistor element 20 of P type.

The MOS capacitive element 10 includes an N+ type impurity region 11, an insulating film 12, and an electrode 13. The MOS capacitive element 10 may further include other members such as the P type well region 14, an element isolation region 18, an N+ type contact region 19, the P+ type contact region 19a, and an interlayer insulating film 503. The N+ type impurity region 11, the P type well region 14, the N+ type contact region 19, and the P+ type contact region 19a are formed in the semiconductor substrate 500. Therefore, the semiconductor substrate 500 includes the N+ type impurity region 11, the P type well region 14, the N+ type contact region 19, and the P+ type contact region 19a.

The N+ type impurity region 11 is formed at the main surface 501 of the semiconductor substrate 500. The N+ type impurity region 11 contains an N type impurity. The N+ type impurity region 11 is formed in the P type well region 14. The insulating film 12 is formed on the main surface 501 of the semiconductor substrate 500 so as to cover the N+ type impurity region 11. The electrode 13 is formed on the insulating film 12. Therefore, the insulating film 12 is disposed between the N+ type impurity region 11 and the electrode 13. The P type well region 14 is formed under the N+ type impurity region 11, the N+ type contact region 19, and the P+ type contact region 19a. The P type well region 14 may be disposed on a P- type epitaxial wafer.

The electrode 13 is disposed so as to face the N+ type impurity region 11 via the insulating film 12. The electrode 13 contains, for example, an N type impurity. The electrode 13 includes, for example, polysilicon containing an N type impurity. The electrode 13 may include a main body portion 13a and an extending portion 13b. For example, the main body portion 13a is disposed over the N+ type impurity region 11. The extending portion 13b extends from the main body portion 13a to an upper side of the element isolation region 18. As described later, an N type impurity may not be implanted into the extending portion 13b. The N type impurity is diffused into the extending portion 13b by activation annealing. Therefore, the extending portion 13b may have an impurity concentration lower than the impurity concentration of the main body portion 13a depending on the conditions of activation annealing. Since the N type impurity is not implanted into the extending portion 13b, the N type impurity is not implanted also into the element isolation region 18. As a result, it is possible to suppress a decrease in withstand voltage due to implantation of a high-concentration impurity into the element isolation region 18. Note that the impurity concentrations in the main body portion 13a and the extending portion 13b may be made uniform by activation annealing.

The interlayer insulating film 503 is formed on the main surface 501 so as to cover the electrode 13. A wiring 16 passing through the interlayer insulating film 503 is connected to the extending portion 13b. The wiring 16 is connected to a portion of the extending portion 13b located over the element isolation region 18.

The element isolation region 18 is formed so as to surround the N+ type impurity region 11 of the MOS capacitive element 10. The element isolation region 18 may be formed at the main surface 501 of the semiconductor substrate 500 between the MOS capacitive element 10 and the MOS transistor element 20. The element isolation region 18 is formed so as to surround an active region in the semiconductor substrate 500. That is, a region surrounded by the element isolation region 18 in the semiconductor substrate 500 is the active region. In the active region, the N+ type impurity region 11 and the N+ type contact region 19 are formed.

The N type impurity region 11 and the element isolation region 18 may be separated from each other. That is, the N type impurity region 11 is formed at an interval from the element isolation region 18 in the X-axis direction and the Y-axis direction in the active region. A part of the P type well region 14 may be formed between the N type impurity region 11 and the element isolation region 18. With such a configuration, it is possible to suppress a decrease in withstand voltage due to implantation of a high-concentration impurity into the element isolation region 18. Note that a part or the whole of the peripheral edge of the N type impurity region 11 may be in contact with the element isolation region 18.

The N+ type contact region 19 is formed at the main surface 501 of the semiconductor substrate 500 between the N+ type impurity region 11 and the element isolation region 18. The N+ type contact region 19 is connected to the N+ type impurity region 11. The N+ type contact region 19 includes, for example, a portion that does not overlap the electrode 13 in plan view. While the N+ type contact region 19 is formed between one end of the N+ type impurity region 11 and the element isolation region 18, a part of the P type well region 14 is sandwiched between the other end of the N+ type impurity region 11 and the element isolation region 18. The N+ type contact region 19 contains an N type impurity. A wiring 17 passing through the interlayer insulating film 503 is connected to the N+ type contact region 19. The MOS capacitive element 10 can be operated by applying a voltage between the wiring 16 and the wiring 17.

The P+ type contact region 19a is formed at the main surface 501 of the semiconductor substrate 500. The P+ type contact region 19a is surrounded by the element isolation region 18. The P+ type contact region 19a and the N+ type contact region 19 are separated by the element isolation region 18. The P+ type contact region 19a is formed on the P type well region 14. A wiring 17a passing through the interlayer insulating film 503 is connected to the P+ type contact region 19a. The P+ type contact region 19a controls the voltage of the P type well region 14.

The MOS transistor element 20 includes a P type impurity region 21, an insulating film 22, an electrode 23, an N+ type impurity region 25a, and an N+ type impurity region 25b. The MOS transistor element 20 may further include a P type well region 24 and an element isolation region 28. The P type impurity region 21, the N+ type impurity region 25a, the N+ type impurity region 25b, and the P type well region 24 are formed in the semiconductor substrate 500. Therefore, the semiconductor substrate 500 includes the P type impurity region 21, the N+ type impurity region 25a, the N+ type impurity region 25b, and the P type well region 24.

The P type impurity region 21 is formed at the main surface 501 of the semiconductor substrate 500. The P type impurity region 21 is formed in an active region surrounded by an element isolation region 26. The P type impurity region 21 contains a P type impurity. The P type impurity region 21 may be a part of the P type well region 24.

The concentration of the impurity contained in the P type impurity region 21 may be lower than the concentration of the impurity contained in the N+ type impurity region 11. In other words, the concentration of the impurity contained in the N+ type impurity region 11 may be higher than the concentration of the impurity contained in the P type impurity region 21. For example, the concentration of the impurity contained in the N+ type impurity region 11 may be twice or more the concentration of the impurity contained in the P type impurity region 21. Also, the concentration of the impurity contained in the N+ type impurity region 11 may be twice to three times the concentration of the impurity contained in the P type impurity region 21. Note that, in the case of the MOS transistor element 20 of P type, the relationship between the concentration of the impurity contained in an N type impurity region 21a described later and the concentration of the impurity contained in the N+ type impurity region 11 is the same as the relationship between the concentration of the impurity contained in the P type impurity region 21 and the concentration of the impurity contained in the N+ type impurity region 11 described above.

The electrode 23 is formed on the insulating film 22. Therefore, the insulating film 22 is disposed between the P type impurity region 21 and the electrode 23. The insulating film 22 is formed on the main surface 501 of the semiconductor substrate 500 so as to cover the P type impurity region 21. The thickness of the insulating film 22 may be the same as the thickness of the insulating film 12. The same thickness means the same thickness in a sense including a measurement error in measuring the thickness and a formation error in forming the insulating film 12 and the insulating film 22. The insulating film 12 and the insulating film 22 may be formed simultaneously.

The electrode 23 is disposed so as to face the P type impurity region 21 via the insulating film 22. The electrode 23 contains, for example, an N type impurity. The impurity concentration in the electrode 23 is lower than the impurity concentration in the electrode 13. In other words, the impurity concentration in the electrode 13 is higher than the impurity concentration in the electrode 23. The impurity concentration in the electrode 13 may be twice or more the impurity concentration in the electrode 23. For example, the impurity concentration in the electrode 13 may be 9.00×10¹⁵ or more and 1.10×10¹⁶ [/cm²] or less. The impurity concentration in the electrode 23 may be 3.60×10¹⁵ or more and 4.50×10¹⁵ [/cm²] or less. Therefore, the impurity concentration in the electrode 13 may be twice to three times the impurity concentration in the electrode 23. With such a configuration, depletion in the electrode 13 can be suppressed, and a decrease in capacitance due to the MOS capacitive element 10 can be suppressed.

The N+ type impurity region 25a and the N+ type impurity region 25b are formed at the main surface 501 of the semiconductor substrate 500. The N+ type impurity region 25a and the N+ type impurity region 25b are formed so as to sandwich the P type impurity region 21. The N+ type impurity region 25a and the N+ type impurity region 25b contain an N type impurity. The N+ type impurity region 25a may be, for example, a source region. The N+ type impurity region 25b may be, for example, a drain region. Note that the N+ type impurity region 25a may be, for example, a collector region. The N+ type impurity region 25b may be, for example, an emitter region.

The P type well region 24 is formed under the P type impurity region 21, the N+ type impurity region 25a, and the N+ type impurity region 25b. The P type well region 24 may be disposed on a P- type epitaxial wafer. The P type well region 24 may be the same as the P type well region 14.

The element isolation region 28 is formed so as to surround the P type impurity region 21, the N+ type impurity region 25a, and the N+ type impurity region 25b. The element isolation region 28 may be formed at the main surface 501 of the semiconductor substrate 500 between the MOS capacitive element 10 and the MOS transistor element 20. The element isolation region 28 is formed so as to surround the active region of the semiconductor substrate 500 in the MOS transistor element 20. That is, a region surrounded by the element isolation region 28 in the semiconductor substrate 500 is the active region. In the active region, the P type impurity region 21, the N+ type impurity region 25a, and the N+ type impurity region 25b are formed.

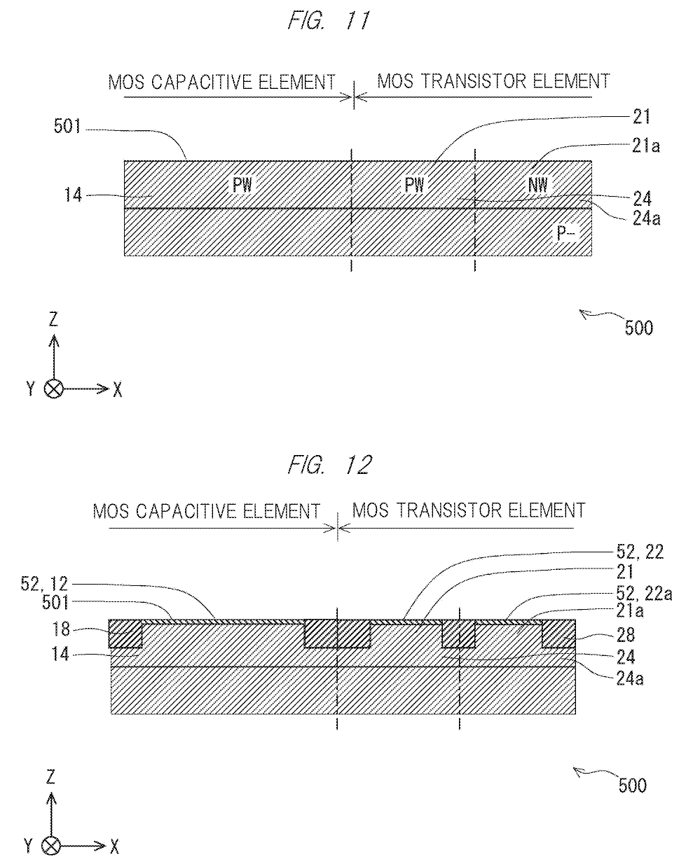

Next, a method of manufacturing the semiconductor device 1 will be described. FIG. 11 to FIG. 15 are cross-sectional views illustrating a method of manufacturing the semiconductor device 1 according to the first embodiment.

As illustrated in FIG. 11, the P type well region 14, the P type well region 24, and an N type well region 24a are formed in the semiconductor substrate 500. The P type well region 14 and the P type well region 24 may be integrally formed. For example, the P type well region 14, the P type well region 24, and the N type well region 24a are formed on a P- type epitaxial wafer. The P type well region 14 is formed in a region of the semiconductor substrate 500 where the MOS capacitive element 10 is formed. The P type well region 24 is formed in a region of the semiconductor substrate 500 where the MOS transistor element 20 of N type is formed. The N type well region 24a is formed in a region of the semiconductor substrate 500 where the MOS transistor element 20 of P type is formed. The P type well region 24 may include the P type impurity region 21. The N type well region 24a may include the N type impurity region 21a.

Next, as illustrated in FIG. 12, the element isolation region 18 and the element isolation region 28 are formed at the main surface 501 of the semiconductor substrate 500. The element isolation region 18 is formed so as to isolate the active region of the semiconductor substrate 500 where the MOS capacitive element 10 is formed from other regions. The element isolation region 28 is formed so as to isolate the active region of the semiconductor substrate 500 where the MOS transistor element 20 is formed from other regions.

Further, an insulating film 52 is formed on the main surface 501 of the semiconductor substrate 500. For example, by oxidizing the main surface 501 of the semiconductor substrate 500 containing silicon by thermal oxidation, a silicon oxide film is formed as the insulating film 52 on the main surface 501. In the present first embodiment, since the N+ type impurity region 11 is not formed at the main surface 501 of the semiconductor substrate 500 in the MOS capacitive element 10, the accelerated oxidation of the insulating film 52 can be suppressed. The insulating film 52 in the region of the semiconductor substrate 500 where the MOS capacitive element 10 is formed is referred to as the insulating film 12. The insulating film 52 in the region of the semiconductor substrate 500 where the MOS transistor element 20 of N type is formed is referred to as the insulating film 22. The insulating film 52 in the region of the semiconductor substrate 500 where the MOS transistor element 20 of P type is formed is referred to as an insulating film 22a. The insulating film 12, the insulating film 22, and the insulating film 22a may be formed simultaneously.

As described above, before an electrode material is formed on the main surface 501 of the semiconductor substrate 500, the element isolation region 18 and the element isolation region 28 are formed at the main surface 501 of the semiconductor substrate 500. Further, before an electrode material is formed on the main surface 501 of the semiconductor substrate 500, the insulating film 52 including the insulating film 12, the insulating film 22, and the insulating film 22a is formed.

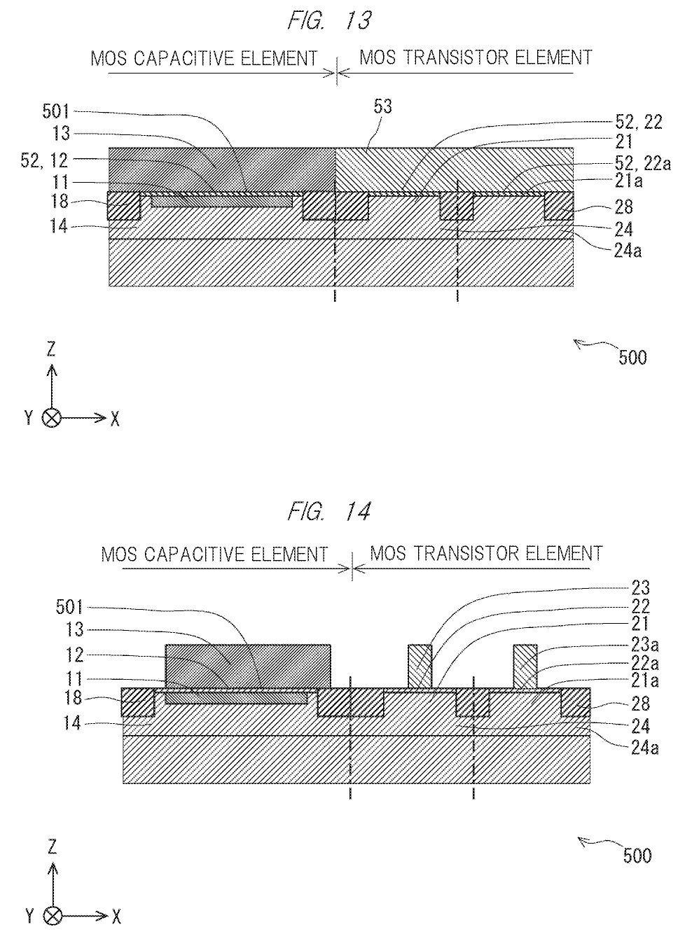

Next, as illustrated in FIG. 13, an electrode material 53 is formed on the main surface 501 of the semiconductor substrate 500 so as to cover the insulating film 52. The electrode material 53 may include, for example, polysilicon. The polysilicon is preferably formed so as not to contain an impurity.

Next, an N type impurity is implanted into a part of the electrode material 53. The part of the electrode material 53 includes a portion formed as the electrode 13 in a later step. For example, an N type impurity is implanted through a mask that covers the other part of the electrode material 53 and opens the part (electrode 13) of the electrode material 53. The N type impurity is not only implanted into the part (electrode 13) of the electrode material 53, but also implanted into the main surface 501 of the semiconductor substrate 500 facing the part (electrode 13) of the electrode material 53 through the electrode material 53 and the insulating film 12. Therefore, the N+ type impurity region 11 is formed at the main surface 501 of the semiconductor substrate 500. The N+ type impurity region 11 is formed in the P type well region 14.

In the present first embodiment, after the deposition of the electrode material 53 such as polysilicon, implantation (gate through) of an impurity into the channel region and pre-doping of the electrode material 53 are simultaneously performed. As a result, the accelerated oxidation of the insulating film 12 and the depletion of the electrode 13 can be suppressed, and capacitance characteristics can be improved. As described above, in the present first embodiment, by implanting an N type impurity into a part (electrode 13) of the electrode material 53 and the main surface 501 of the semiconductor substrate 500 facing the part (electrode 13) of the electrode material 53 via the insulating film 52, the electrode 13 is formed in a part of the electrode material 53, and the N+ type impurity region 11 is formed. Thereafter, activation annealing may be performed.

When the N+ type impurity region 11 is formed, the N+ type impurity region 11 and the element isolation region 18 may be separated from each other. For example, the mask covers the element isolation region 18, and an opening that is opened in the mask may be so small as to be included in the active region surrounded by the element isolation region 18. By introducing the N type impurity with such a mask, the N+ type impurity region 11 and the element isolation region 18 can be separated from each other.

Next, as illustrated in FIG. 14, the electrode material 53 is processed into the electrode 13, the electrode 23, and an electrode 23a. For example, a mask having openings corresponding to portions of the electrode material 53 other than the electrode 13, the electrode 23, and the electrode 23a is disposed on the electrode material 53, and the electrode material 53 is etched such that the portions other than the electrode 13, the electrode 23, and the electrode 23a are removed. Thus, the electrode material 53 is processed into the electrode 13, the electrode 23, and the electrode 23a. As described above, in the present first embodiment, the portions other than the electrode 13, the electrode 23, and the electrode 23a are removed from the electrode material 53 to form the electrode 13, the electrode 23, and the electrode 23a.

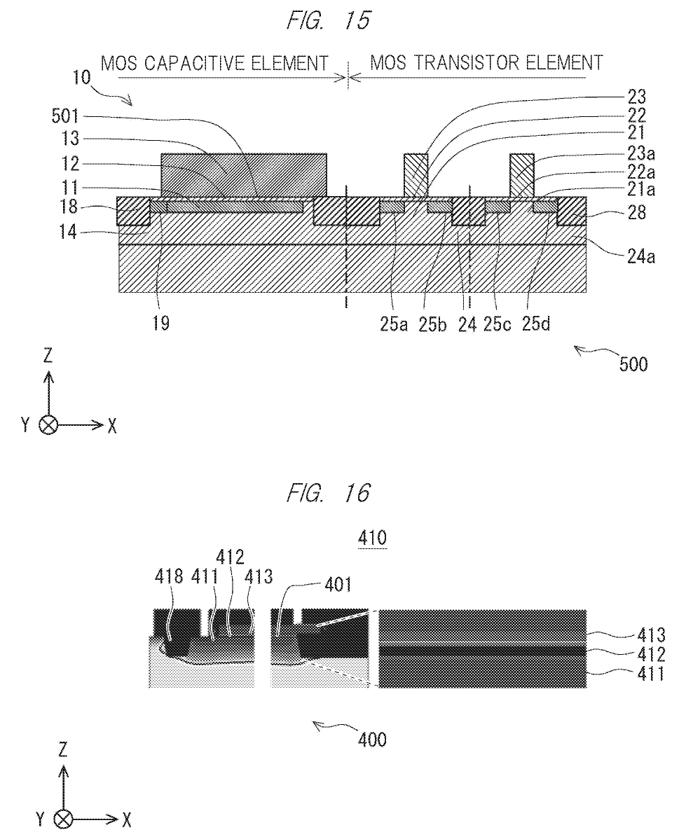

Next, as illustrated in FIG. 15, the N+ type contact region 19, the N+ type impurity region 25a, and the N+ type impurity region 25b are formed. For example, the N type impurity is implanted into the semiconductor substrate 500 through a mask that covers a region where the MOS transistor element 20 of P type is formed and has openings for a region where the MOS capacitive element 10 and the MOS transistor element 20 of N type are formed. As a result, the N+ type contact region 19 containing an N type impurity is formed in a portion of the semiconductor substrate 500 between the N+ type impurity region 11 and the element isolation region 18 and not overlapping the electrode 13. Also, the N+ type impurity region 25a and the N+ type impurity region 25b are formed at the main surface 501 of the semiconductor substrate 500 so as to sandwich the P type impurity region 21. In this step, an N type impurity may be implanted into the electrode 13 and the electrode 23. Thereafter, activation annealing may be performed.

Also, a P+ type impurity region 25c and a P+ type impurity region 25d are formed. For example, a P type impurity is implanted into the semiconductor substrate 500 through a mask that covers a region where the MOS capacitive element 10 and the MOS transistor element 20 of N type are formed and has openings for a region where the MOS transistor element 20 of P type is formed. As a result, the P+ type impurity region 25c and the P+ type impurity region 25d are formed at the main surface 501 of the semiconductor substrate 500 so as to sandwich the N type impurity region 21a. In this step, a P type impurity may be implanted into the electrode 23a. Thereafter, activation annealing may be performed.

The N+ type impurity region 11 is formed at the main surface 501 of the semiconductor substrate 500 so as to face the electrode 13. The P type impurity region 21 is formed at the main surface 501 of the semiconductor substrate 500 so as to face the electrode 23. The N type impurity region 21a is formed at the main surface 501 of the semiconductor substrate 500 so as to face the electrode 23a.

The insulating film 52 between the N+ type impurity region 11 and the electrode 13 is the insulating film 12. The insulating film 52 between the P type impurity region 21 and the electrode 23 is the insulating film 22. The insulating film 52 between the N type impurity region 21a and the electrode 23a is the insulating film 22a. In this way, the semiconductor device 1 of the present first embodiment including the MOS capacitive element 10, the MOS transistor element 20 of N type, and the MOS transistor element 20 of P type can be manufactured.

The MOS capacitive element 10 includes the N+ type impurity region 11, the insulating film 12, and the electrode 13. The MOS transistor element 20 of N type includes the P type impurity region 21, the insulating film 22, the electrode 23, the N+ type impurity region 25a, and the N+ type impurity region 25b. The MOS transistor element 20 of P type includes the N type impurity region 21a, the insulating film 22a, the electrode 23a, the P+ type impurity region 25c, and the P+ type impurity region 25d.

Next, effects of the present first embodiment will be described. The MOS capacitive element 10 of the present first embodiment includes the N+ type impurity region 11 containing a high-concentration impurity in a channel region as compared with the MOS capacitive element 110 of first comparative example. Therefore, the MOS capacitive element 10 of the present first embodiment can shift a threshold voltage to a low voltage side, and can operate in the accumulation region. As a result, the bias dependency of the MOS capacitive element 10 can be reduced regardless of the voltage condition.

Also, in the MOS capacitive element 10 of the present first embodiment, the insulating film 12 is not formed after a high-concentration impurity is implanted into the channel region. In the MOS capacitive element 10 of the present first embodiment, the insulating film 12 is formed before the N+ type impurity region 11 is formed. Therefore, the MOS capacitive element 10 of the present first embodiment can suppress an increase in the thickness of the insulating film 12 due to accelerated oxidation. As a result, the capacitance characteristics of the MOS capacitive element 10 can be improved as compared with the MOS capacitive element 210 of second comparative example.

Further, in the present first embodiment, an impurity is simultaneously implanted into the portion of the electrode 13 of the electrode material 53 and the N+ type impurity region 11 located on the main surface 501 of the semiconductor substrate 500. As a result, as compared with the MOS capacitive element 310 of third comparative example, the accelerated oxidation of the insulating film 12 and the depletion of the electrode 13 can be suppressed, and capacitance characteristics of the MOS capacitive element 10 can be improved.

FIG. 16 is a simulation result illustrating capacitance of a MOS capacitive element 410 of fourth comparative example. FIG. 16 also illustrates a structure of the MOS capacitive element 410 of fourth comparative example. As illustrated in FIG. 16, the MOS capacitive element 410 of fourth comparative example includes an N+ type impurity region 411, an insulating film 412, and an electrode 413. The N+ type impurity region 411 is formed at a main surface 401 of a semiconductor substrate 400. The insulating film 412 and the electrode 413 are formed on the main surface 401 of the semiconductor substrate 400. The N+ type impurity region 411 is formed in an active region surrounded by an element isolation region 418. In the MOS capacitive element 410 of fourth comparative example, the N+ type impurity region 411 is formed by implanting an N type impurity into the main surface 401 of the semiconductor substrate 400, and then the insulating film 412 is formed. Also, in the MOS capacitive element 410 of fourth comparative example, implantation of the N type impurity into the electrode 413 in advance for suppressing depletion of the electrode 413 is omitted. In fourth comparative example, the insulating film 412 becomes thicker due to accelerated oxidation. In addition, the lower portion of the electrode 413 is depleted.

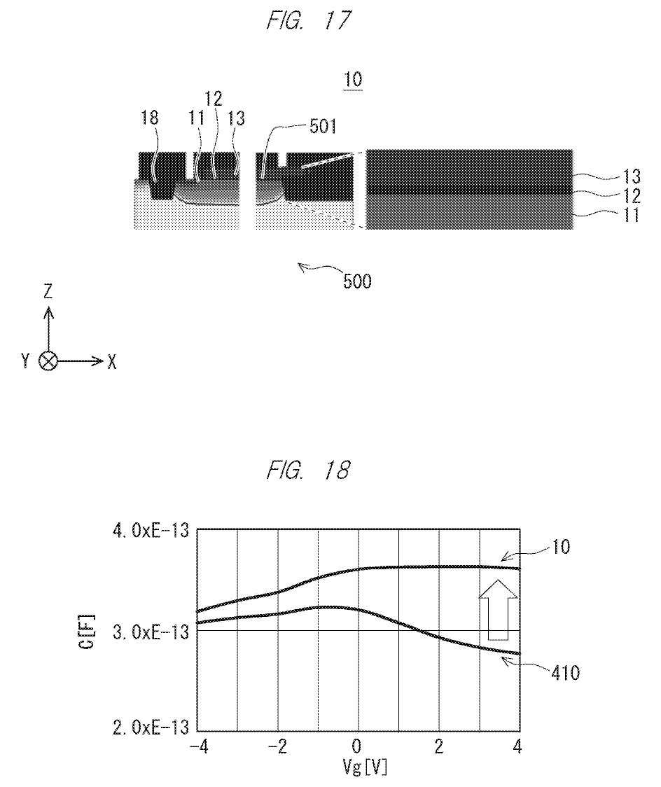

FIG. 17 is a simulation result illustrating the capacitance of the MOS capacitive element 10 of the first embodiment. FIG. 17 also illustrates a structure of the MOS capacitive element 10 of the first embodiment. As illustrated in FIG. 17, the MOS capacitive element 10 of the first embodiment can suppress the accelerated oxidation of the insulating film 12. In addition, the MOS capacitive element 10 of the first embodiment can suppress the depletion of the lower portion of the electrode 13.

FIG. 18 is a graph illustrating the capacitances of the MOS capacitive element 10 of the first embodiment and the MOS capacitive element 410 of fourth comparative example, where the horizontal axis represents a voltage V and the vertical axis represents a capacitance C. As illustrated in FIG. 18, the MOS capacitive element 10 of the present first embodiment can improve a capacitance value by 28% or more as compared with the MOS capacitive element 410 of fourth comparative example.

Although the invention made by the present inventor has been specifically described based on the embodiment, the present invention is not limited to the above embodiment, and it goes without saying that various modifications can be made within the range not departing from the gist of the present invention. For example, appropriate combinations of the configurations of the first comparative example to the fourth comparative example and the first embodiment are also within the scope of the technical idea of the embodiment.

What is claimed is:

1. A semiconductor device comprising:
a MOS capacitive element; and
a MOS transistor element,
wherein the MOS capacitive element includes:
a first impurity region formed in a semiconductor substrate and disposed at a main surface of the semiconductor substrate;
a first insulating film formed on the main surface of the semiconductor substrate so as to cover the first impurity region; and
a first electrode formed on the first impurity region via the first insulating film,
wherein the MOS transistor element includes:
a second impurity region formed in the semiconductor substrate and disposed at the main surface of the semiconductor substrate;
a second insulating film formed on the main surface of the semiconductor substrate so as to cover the second impurity region; and
a second electrode formed on the second impurity region via the second insulating film, and
wherein an impurity concentration in the first electrode is higher than an impurity concentration in the second electrode.

2. The semiconductor device according to claim 1,
wherein the impurity concentration in the first electrode is twice or more the impurity concentration in the second electrode.

3. The semiconductor device according to claim 1,
wherein an impurity concentration in the first impurity region is higher than an impurity concentration in the second impurity region.

4. The semiconductor device according to claim 1,
wherein a thickness of the first insulating film is the same as a thickness of the second insulating film.

5. The semiconductor device according to claim 1,
wherein the first impurity region contains an impurity of a first conductivity type,
wherein the first electrode contains an impurity of the first conductivity type,
wherein the second impurity region contains an impurity of a second conductivity type opposite to the first conductivity type,
wherein the second electrode contains an impurity of the first conductivity type,
wherein the MOS capacitive element further includes a first well region of the second conductivity type formed in the semiconductor substrate,
wherein the first impurity region is formed in the first well region, and
wherein the MOS transistor element includes:
a third impurity region of the first conductivity type and a fourth impurity region of the first conductivity type formed in the semiconductor substrate, disposed at the main surface of the semiconductor substrate, and formed so as to sandwich the second impurity region; and
a second well region of the second conductivity type formed in the semiconductor substrate and disposed under the second impurity region, the third impurity region, and the fourth impurity region.

6. The semiconductor device according to claim 1, further comprising an element isolation region formed in the semiconductor substrate and disposed at the main surface of the semiconductor substrate,
wherein the element isolation region surrounds the first impurity region in plan view.

7. The semiconductor device according to claim 6,
wherein the first impurity region and the element isolation region are separated from each other.

8. The semiconductor device according to claim 6,
wherein the MOS capacitive element further includes a contact region formed in the semiconductor substrate and disposed at the main surface of the semiconductor substrate and between the first impurity region and the element isolation region,
wherein the contact region contains an impurity of a first conductivity type, and
wherein the first impurity region is electrically connected to the contact region.

9. The semiconductor device according to claim 6,
wherein the first electrode includes:
a main body portion disposed over the first impurity region; and
an extending portion extending from the main body portion to an upper side of the element isolation region.

10. The semiconductor device according to claim 9,
wherein the extending portion has an impurity concentration lower than an impurity concentration in the main body portion.

11. A method of manufacturing a semiconductor device including a MOS capacitive element and a MOS transistor element, the method comprising:
forming a first insulating film and a second insulating film on a main surface of a semiconductor substrate;
forming an electrode material on the main surface of the semiconductor substrate so as to cover the first insulating film and the second insulating film, the electrode material having a first portion and a second portion;
wherein the first portion of the electrode material is located on the first insulating film, and the second portion of the electrode material is located on the second insulating film;
forming a first impurity region in the semiconductor substrate by implanting an impurity into the first portion of the electrode material and a portion of the semiconductor substrate located under the first portion of the electrode material in a state where the second portion of the electrode material is covered with a mask; and
forming a first electrode from the first portion and forming a second electrode from the second portion by processing the electrode material,
wherein the MOS capacitive element includes the first impurity region, the first insulating film, and the first electrode,
wherein the MOS transistor element includes a second impurity region disposed in the semiconductor substrate, the second insulating film, and the second electrode, and
wherein an impurity concentration in the first electrode is higher than an impurity concentration in the second electrode.

12. The method according to claim 11,
wherein the impurity concentration in the first electrode is twice or more the impurity concentration in the second electrode.

13. The method according to claim 11,
wherein an impurity concentration in the first impurity region is higher than an impurity concentration in the second impurity region.

14. The method according to claim 11,
wherein a thickness of the first insulating film is the same as a thickness of the second insulating film.

15. The method according to claim 11, further comprising:
before forming the first insulating film and the second insulating film, forming a first well region of a second conductivity type opposite to a first conductivity type and a second well region of the second conductivity type in the semiconductor substrate; and
after forming the first electrode and the second electrode, forming a third impurity region of the first conductivity type and a fourth impurity region of the first conductivity type in the second well region by implanting an impurity into the first electrode, the second electrode, and the semiconductor substrate,
wherein the first impurity region contains an impurity of the first conductivity type,
wherein the first electrode contains an impurity of the first conductivity type,
wherein the second impurity region contains an impurity of the second conductivity type,
wherein the second electrode contains an impurity of the first conductivity type,
wherein the first impurity region is formed in the first well region,
wherein the MOS capacitive element further includes the first well region,
wherein the third impurity region and the fourth impurity region are disposed at the main surface of the semiconductor substrate so as to sandwich the second impurity region, and
wherein the MOS transistor element includes the third impurity region, the fourth impurity region, and the second well region.

16. The method according to claim 11, further comprising:
before forming the electrode material, forming an element isolation region in the semiconductor substrate and at the main surface of the semiconductor substrate,
wherein the element isolation region surrounds the first impurity region in plan view.

17. The method according to claim 16,
wherein the first impurity region is formed so as to be separated from the element isolation region in forming the first impurity region.

18. The method according to claim 15, further comprising:
before forming the electrode material, forming an element isolation region in the semiconductor substrate and at the main surface of the semiconductor substrate,
wherein the element isolation region surrounds the first impurity region,
wherein a contact region is formed in the semiconductor substrate by implanting the impurity into the semiconductor substrate in forming the third impurity region and the fourth impurity region,
wherein the contact region is disposed at the main surface of the semiconductor substrate and between the first impurity region and the element isolation region,
wherein the contact region contains an impurity of the first conductivity type, and
wherein the first impurity region is electrically connected to the contact region.

19. The method according to claim 16,
wherein the first electrode includes:
a main body portion disposed over the first impurity region; and
an extending portion extending from the main body portion to an upper side of the element isolation region.

20. The method according to claim 19,
wherein the extending portion has an impurity concentration lower than an impurity concentration in the main body portion.
